(19) United States
(12) Patent Application Publication
(10) Pub. No.: US 2015/0144928 A1
(43) Pub. Date: May 28, 2015

(54) BURIED GRID FOR OUTCOUPLING WAVEGUIDED LIGHT IN OLEDs

(71) Applicant: The Regents of the University of Michigan, Ann Arbor, MI (US)

(72) Inventors: Stephen R. FORREST, Ann Arbor, MI (US); Michael SLOOTSKY, Ann Arbor, MI (US); Yue QU, Ann Arbor, MI (US)

(21) Appl. No.: 14/555,031

(22) Filed: Nov. 26, 2014

Related U.S. Application Data
(60) Provisional application No. 61/909,351, filed on Nov. 26, 2013.

(51) Int. Cl. H01L 51/52; H01L 27/32; H01L 51/56

(52) U.S. Cl. CPC H01L 51/5275; H01L 51/56; H01L 27/3204
USPC 257/40; 438/29

(57) ABSTRACT

Light-emitting devices are provided that include a mixed-index layer having a buried grid disposed below a bottom electrode of the device. The grid provides improved outcoupling into glass and air modes relative to techniques that omit such a grid and/or that use a conventional low-index grid embedded in the emissive layers of the device.

### CROSS-REFERENCE TO RELATED APPLICATIONS

This application claims priority to U.S. Provisional Patent Application Ser. No. 61/909,351, filed Nov. 26, 2013, the entire contents of which is incorporated herein by reference.

### STATEMENT REGARDING GOVERNMENT RIGHTS

This application was made with government support under Contract No. DE-SC0001013 awarded by the U.S. Department of Energy (DOE), Office of Basic Energy Sciences, as part of the Center for Energy Nanoscience, Energy Frontier Research Center. The government may have certain rights in this invention.

### PARTIES TO A JOINT RESEARCH AGREEMENT

The claimed invention was made by, on behalf of, and/or in connection with one or more of the following parties to a joint university corporation research agreement: Regents of the University of Michigan, Princeton University, University of Southern California, and the Universal Display Corporation. The agreement was in effect on and before the date the claimed invention was made, and the claimed invention was made as a result of activities undertaken within the scope of the agreement.

### FIELD OF THE INVENTION

The present invention relates to techniques for fabricating light emitting devices such as OLEDs having a mixed-index layer, and devices such as organic light emitting diodes and other devices, including the same.

### BACKGROUND

Opto-electronic devices that make use of organic materials are becoming increasingly desirable for a number of reasons. Many of the materials used to make such devices are relatively inexpensive, so organic opto-electronic devices have the potential for cost advantages over inorganic devices. In addition, the inherent properties of organic materials, such as their flexibility, may make them well suited for particular applications such as fabrication on a flexible substrate. Examples of organic opto-electronic devices include organic light emitting devices (OLEDs), organic phototransistors, organic photovoltaic cells, and organic photodetectors. For OLEDs, the organic materials may have performance advantages over conventional materials. For example, the wavelength at which an organic emissive layer emits light may generally be readily tuned with appropriate dopants.

OLEDs make use of thin organic films that emit light when voltage is applied across the device. OLEDs are becoming an increasingly interesting technology for use in applications such as flat panel displays, illumination, and backlighting. Several OLED materials and configurations are described in U.S. Pat. Nos. 5,844,363, 6,303,238, and 5,707,745, which are incorporated herein by reference in their entirety.

One application for phosphorescent emissive molecules is a full color display. Industry standards for such a display call for pixels adapted to emit particular colors, referred to as “saturated” colors. In particular, these standards call for saturated red, green, and blue pixels. Color may be measured using CIE coordinates, which are well known to the art.

One example of a green emissive molecule is tris(2-phenylpyridine) iridium, denoted Ir(ppy)₃, which has the following structure:

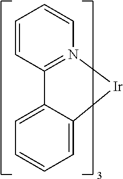

In this, and later figures herein, we depict the dative bond from nitrogen to metal (here, Ir) as a straight line.

As used herein, the term “organic” includes polymeric materials as well as small molecule organic materials that may be used to fabricate organic opto-electronic devices. “Small molecule” refers to any organic material that is not a polymer, and “small molecules” may actually be quite large. Small molecules may include repeat units in some circumstances. For example, using a long chain alkyl group as a substituent does not remove a molecule from the “small molecule” class. Small molecules may also be incorporated into polymers, for example as a pendent group on a polymer backbone or as a part of the backbone. Small molecules may also serve as the core moiety of a dendrimer, which consists of a series of chemical shells built on the core moiety. The core moiety of a dendrimer may be a fluorescent or phosphorescent small molecule emitter. A dendrimer may be a “small molecule,” and it is believed that all dendrimers currently used in the field of OLEDs are small molecules.

As used herein, “top” means furthest away from the substrate, while “bottom” means closest to the substrate. Where a first layer is described as “disposed over” a second layer, the first layer is disposed further away from substrate. There may be other layers between the first and second layer, unless it is specified that the first layer is “in contact with” the second layer. For example, a cathode may be described as “disposed over” an anode, even though there are various organic layers in between.

As used herein, “solution processible” means capable of being dissolved, dispersed, or transported in and/or deposited from a liquid medium, either in solution or suspension form.

A ligand may be referred to as “photoactive” when it is believed that the ligand directly contributes to the photoactive properties of an emissive material. A ligand may be referred to as “ancillary” when it is believed that the ligand does not contribute to the photoactive properties of an emissive material, although an ancillary ligand may alter the properties of a photoactive ligand.

As used herein, and as would be generally understood by one skilled in the art, a first “Highest Occupied Molecular Orbital” (HOMO) or “Lowest Unoccupied Molecular Orbital” (LUMO) energy level is “greater than” or “higher than” a second HOMO or LUMO energy level if the first energy level is closer to the vacuum energy level. Since ionization potentials (IP) are measured as a negative energy relative to a vacuum level, a higher HOMO energy level corresponds to an IP having a smaller absolute value (an IP that is less negative). Similarly, a higher LUMO energy level corresponds to an electron affinity (EA) having a smaller absolute value (an EA that is less negative). On a conventional energy level diagram, with the vacuum level at the top, the LUMO energy level of a material is higher than the HOMO energy level of the same material. A “higher” HOMO or LUMO energy level appears closer to the top of such a diagram than a “lower” HOMO or LUMO energy level.

As used herein, and as would be generally understood by one skilled in the art, a first work function is “greater than” or “higher than” a second work function if the first work function has a higher absolute value. Because work functions are generally measured as negative numbers relative to vacuum level, this means that a “higher” work function is more negative. On a conventional energy level diagram, with the vacuum level at the top, a “higher” work function is illustrated as further away from the vacuum level in the downward direction. Thus, the definitions of HOMO and LUMO energy levels follow a different convention than work functions.

More details on OLEDs, and the definitions described above, can be found in U.S. Pat. No. 7,279,704, which is incorporated herein by reference in its entirety.

### SUMMARY OF THE INVENTION

According to an embodiment, a device such as an OLED includes a substrate; a mixed-index layer disposed above the substrate, which includes a first material and a second material having different refractive indices, the first and second materials being disposed in a periodic pattern such as a grid. An electrode may be disposed above the mixed-index layer, and one or more an organic emissive layers may be disposed above the electrode. A second electrode may be disposed above the organic emissive layer. The grid may be, for example, rectangular, triangular, hexagonal, or any other periodic and/or shape-filling grid pattern.

In embodiments, the grid may have a periodicity of 1-10 μm, and/or a line width of 0.1-5 μm. A material that makes up the grid line structure may have a refractive index within 0.1 of a refractive index of the first electrode. The difference between refractive indices of the materials in the mixed-index layer may be at least 0.1, at least 0.4, or any other suitable difference.

The refractive index of the host material may be in the range of about 1.0 to 3.0. The refractive index of the grid line material may be in the range of about 1.0 to 1.5. The mixed-index layer ma have a thickness of about 10 nm-2 μm, and/or it may be planar to within a tolerance of 0.1-2 nm.

In an embodiment, a device as disclosed herein may be fabricated by fabricating a mixed-index layer in a pattern over a substrate, which includes a high-index material and a low-index material; depositing a first electrode over the patterned mixed-index layer; depositing an organic emissive layer over the first electrode; and depositing a second electrode over the organic emissive layer. In an embodiment, fabrication of the mixed-index layer may include depositing a first high-index material in a layer over the substrate; removing the pattern from the first high-index material to form a patterned void; and depositing a second high-index material in a layer over the remaining first high-index material and over the patterned void. In an embodiment, fabrication of the mixed-index layer may include depositing a first high-index material over the substrate; removing the pattern from the first high-index material; depositing a low-index material over the high-index material and in the pattern. In some embodiments, the low-index material may be removed from above the remaining high-index material. Each technique may be used to fabricate each of the device structures and arrangements disclosed herein.

According to an embodiment, a first device comprising a first organic light emitting device is also provided. The first organic light emitting device can include an anode, a cathode, and an organic layer, disposed between the anode and the cathode. The organic layer can include a mixed-index layer providing a buried grid as disclosed herein. The first device can be a consumer product, an organic light-emitting device, and/or a lighting panel.

### BRIEF DESCRIPTION OF THE DRAWINGS

FIG. 1 shows an organic light emitting device.

FIG. 2 shows an inverted organic light emitting device that does not have a separate electron transport layer.

FIG. 3 shows an example structure of a device including a buried grid outcoupling layer as disclosed herein.

FIG. 4 shows a schematic representation of a portion of a device having a buried grid outcoupling layer as described herein.

FIG. 5A shows simulation results of the amount of light outcoupled to glass and air modes for a device as disclosed herein.

FIG. 5B shows simulation results of the amount of light outcoupled to glass and air modes as a function of the host refractive index with and without an optimized grid for a device as disclosed herein.

FIG. 6 shows simulation results showing the amount of light outcoupled to glass and air modes at different grid periodicities as disclosed herein.

FIG. 7 shows the external quantum efficiency as a function of the grid refractive index for a variety of host refractive indices for a device as disclosed herein.

### DETAILED DESCRIPTION

Generally, an OLED comprises at least one organic layer disposed between and electrically connected to an anode and a cathode. When a current is applied, the anode injects holes and the cathode injects electrons into the organic layer(s). The injected holes and electrons each migrate toward the oppositely charged electrode. When an electron and hole localize on the same molecule, an “exciton,” which is a localized electron-hole pair having an excited energy state, is formed. Light is emitted when the exciton relaxes via a photoemissive mechanism. In some cases, the exciton may be localized on an excimer or an exciplex. Non-radiative mechanisms, such as thermal relaxation, may also occur, but are generally considered undesirable.

The initial OLEDs used emissive molecules that emitted light from their singlet states (“fluorescence”) as disclosed, for example, in U.S. Pat. No. 4,769,292, which is incorporated by reference in its entirety. Fluorescent emission generally occurs in a time frame of less than 10 nanoseconds.

More recently, OLEDs having emissive materials that emit light from triplet states (“phosphorescence”) have been demonstrated. Baldo et al., “Highly Efficient Phosphorescent Emission from Organic Electroluminescent Devices,” Nature, vol. 395, 151-154, 1998; (“Baldo-I”) and Baldo et al., “Very high-efficiency green organic light-emitting devices based on electrophosphorescence,” Appl. Phys. Lett., vol. 75, No. 3, 4-6 (1999) (“Baldo-II”), which are incorporated by reference in their entireties. Phosphorescence is described in more detail in U.S. Pat. No. 7,279,704 at cols. 5-6, which are incorporated by reference.

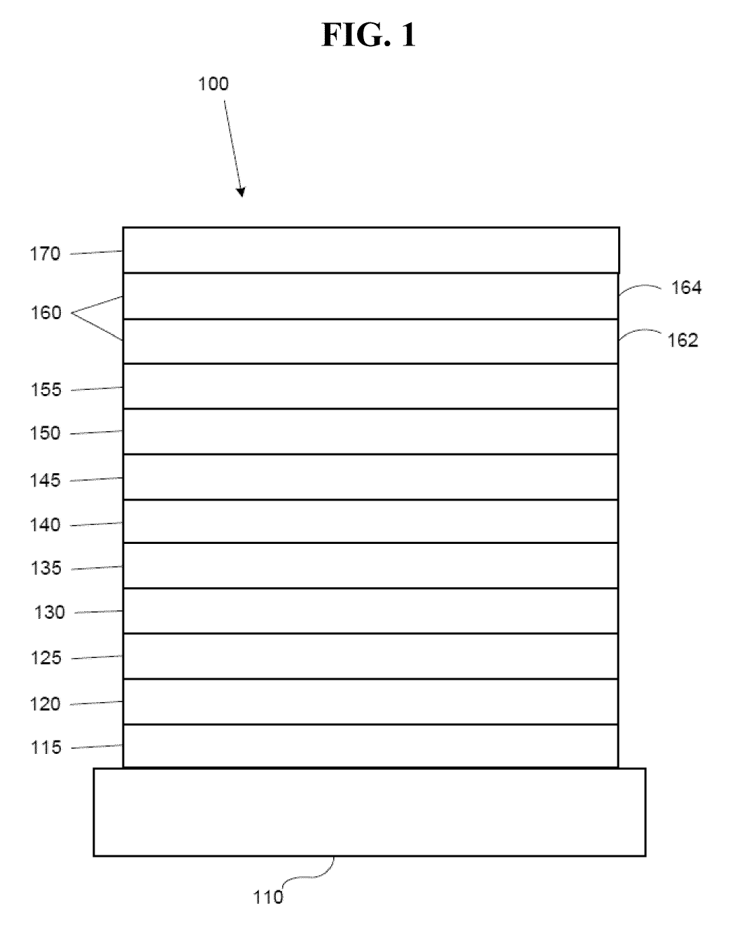

FIG. 1 shows an organic light emitting device 100. The figures are not necessarily drawn to scale. Device 100 may include a substrate 110, an anode 115, a hole injection layer 120, a hole transport layer 125, an electron blocking layer 130, an emissive layer 135, a hole blocking layer 140, an electron transport layer 145, an electron injection layer 150, a protective layer 155, a cathode 160, and a barrier layer 170. Cathode 160 is a compound cathode having a first conductive layer 162 and a second conductive layer 164. Device 100 may be fabricated by depositing the layers described, in order. The properties and functions of these various layers, as well as example materials, are described in more detail in U.S. Pat. No. 7,279,704 at cols. 6-10, which are incorporated by reference.

More examples for each of these layers are available. For example, a flexible and transparent substrate-anode combination is disclosed in U.S. Pat. No. 5,844,363, which is incorporated by reference in its entirety. An example of a p-doped hole transport layer is m-MTDATA doped with F₄-TCNQ at a molar ratio of 50:1, as disclosed in U.S. Patent Application Publication No. 2003/0230980, which is incorporated by reference in its entirety. Examples of emissive and host materials are disclosed in U.S. Pat. No. 6,303,238 to Thompson et al., which is incorporated by reference in its entirety. An example of an n-doped electron transport layer is BPhen doped with Li at a molar ratio of 1:1, as disclosed in U.S. Patent Application Publication No. 2003/0230980, which is incorporated by reference in its entirety. U.S. Pat. Nos. 5,703,436 and 5,707,745, which are incorporated by reference in their entireties, disclose examples of cathodes including compound cathodes having a thin layer of metal such as Mg:Ag with an overlying transparent, electrically-conductive, sputter-deposited ITO layer. The theory and use of blocking layers is described in more detail in U.S. Pat. No. 6,097,147 and U.S. Patent Application Publication No. 2003/0230980, which are incorporated by reference in their entireties. Examples of injection layers are provided in U.S. Patent Application Publication No. 2004/0174116, which is incorporated by reference in its entirety. A description of protective layers may be found in U.S. Patent Application Publication No. 2004/0174116, which is incorporated by reference in its entirety.

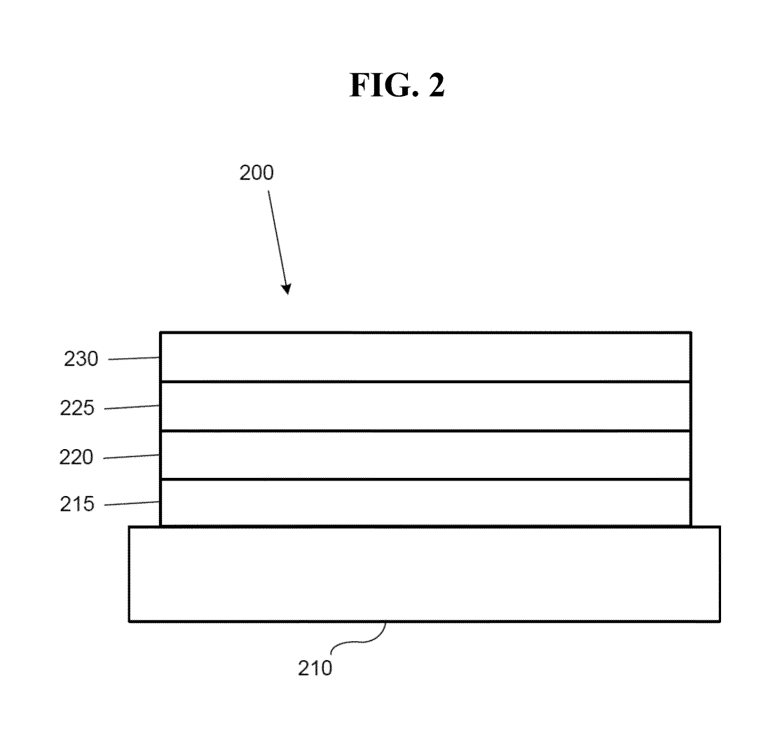

FIG. 2 shows an inverted OLED 200. The device includes a substrate 210, a cathode 215, an emissive layer 220, a hole transport layer 225, and an anode 230. Device 200 may be fabricated by depositing the layers described, in order. Because the most common OLED configuration has a cathode disposed over the anode, and device 200 has cathode 215 disposed under anode 230, device 200 may be referred to as an “inverted” OLED. Materials similar to those described with respect to device 100 may be used in the corresponding layers of device 200. FIG. 2 provides one example of how some layers may be omitted from the structure of device 100.

The simple layered structure illustrated in FIGS. 1 and 2 is provided by way of non-limiting example, and it is understood that embodiments of the invention may be used in connection with a wide variety of other structures. The specific materials and structures described are exemplary in nature, and other materials and structures may be used. Functional OLEDs may be achieved by combining the various layers described in different ways, or layers may be omitted entirely, based on design, performance, and cost factors. Other layers not specifically described may also be included. Materials other than those specifically described may be used. Although many of the examples provided herein describe various layers as comprising a single material, it is understood that combinations of materials, such as a mixture of host and dopant, or more generally a mixture, may be used. Also, the layers may have various sublayers. The names given to the various layers herein are not intended to be strictly limiting. For example, in device 200, hole transport layer 225 transports holes and injects holes into emissive layer 220, and may be described as a hole transport layer or a hole injection layer. In one embodiment, an OLED may be described as having an “organic layer” disposed between a cathode and an anode. This organic layer may comprise a single layer, or may further comprise multiple layers of different organic materials as described, for example, with respect to FIGS. 1 and 2.

Structures and materials not specifically described may also be used, such as OLEDs comprised of polymeric materials (PLEDs) such as disclosed in U.S. Pat. No. 5,247,190 to Friend et al., which is incorporated by reference in its entirety. By way of further example, OLEDs having a single organic layer may be used. OLEDs may be stacked, for example as described in U.S. Pat. No. 5,707,745 to Forrest et al, which is incorporated by reference in its entirety. The OLED structure may deviate from the simple layered structure illustrated in FIGS. 1 and 2. For example, the substrate may include an angled reflective surface to improve outcoupling, such as a mesa structure as described in U.S. Pat. No. 6,091,195 to Forrest et al., and/or a pit structure as described in U.S. Pat. No. 5,834,893 to Bulovic et al., which are incorporated by reference in their entireties.

Unless otherwise specified, any of the layers of the various embodiments may be deposited by any suitable method. For the organic layers, preferred methods include thermal evaporation, ink-jet, such as described in U.S. Pat. Nos. 6,013,982 and 6,087,196, which are incorporated by reference in their entireties, organic vapor phase deposition (OVPD), such as described in U.S. Pat. No. 6,337,102 to Forrest et al., which is incorporated by reference in its entirety, and deposition by organic vapor jet printing (OVJP), such as described in U.S. Pat. No. 7,431,968, which is incorporated by reference in its entirety. Other suitable deposition methods include spin coating and other solution based processes. Solution based processes are preferably carried out in nitrogen or an inert atmosphere. For the other layers, preferred methods include thermal evaporation. Preferred patterning methods include deposition through a mask, cold welding such as described in U.S. Pat. Nos. 6,294,398 and 6,468,819, which are incorporated by reference in their entireties, and patterning associated with some of the deposition methods such as ink jet and OVJD. Other methods may also be used. The materials to be deposited may be modified to make them compatible with a particular deposition method. For example, substituents such as alkyl and aryl groups, branched or unbranched, and preferably containing at least 3 carbons, may be used in small molecules to enhance their ability to undergo solution processing. Substituents having 20 carbons or more may be used, and 3-20 carbons is a preferred range. Materials with asymmetric structures may have better solution processibility than those having symmetric structures, because asymmetric materials may have a lower tendency to recrystallize. Dendrimer substituents may be used to enhance the ability of small molecules to undergo solution processing.

Devices fabricated in accordance with embodiments of the present invention may further optionally comprise a barrier layer. One purpose of the barrier layer is to protect the electrodes and organic layers from damaging exposure to harmful species in the environment including moisture, vapor and/or gases, etc. The barrier layer may be deposited over, under or next to a substrate, an electrode, or over any other parts of a device including an edge. The barrier layer may comprise a single layer, or multiple layers. The barrier layer may be formed by various known chemical vapor deposition techniques and may include compositions having a single phase as well as compositions having multiple phases. Any suitable material or combination of materials may be used for the barrier layer. The barrier layer may incorporate an inorganic or an organic compound or both. The preferred barrier layer comprises a mixture of a polymeric material and a non-polymeric material as described in U.S. Pat. No. 7,968,146, PCT Pat. Application Nos. PCT/US2007/023098 and PCT/US2009/042829, which are herein incorporated by reference in their entireties. To be considered a “mixture”, the aforesaid polymeric and non-polymeric materials comprising the barrier layer should be deposited under the same reaction conditions and/or at the same time. The weight ratio of polymeric to non-polymeric material may be in the range of 95:5 to 5:95. The polymeric material and the non-polymeric material may be created from the same precursor material. In one example, the mixture of a polymeric material and a non-polymeric material consists essentially of polymeric silicon and inorganic silicon.

Devices fabricated in accordance with embodiments of the invention can be incorporated into a wide variety of electronic component modules (or units) that can be incorporated into a variety of electronic products or intermediate components. Examples of such electronic products or intermediate components include display screens, lighting devices such as discrete light source devices or lighting panels, etc. that can be utilized by the end-user product manufacturers. Such electronic component modules can optionally include the driving electronics and/or power source(s). Devices fabricated in accordance with embodiments of the invention can be incorporated into a wide variety of consumer products that have one or more of the electronic component modules (or units) incorporated therein. Such consumer products would include any kind of products that include one or more light source(s) and/or one or more of some type of visual displays. Some examples of such consumer products include flat panel displays, computer monitors, medical monitors, televisions, billboards, lights for interior or exterior illumination and/or signaling, heads-up displays, fully or partially transparent displays, flexible displays, laser printers, telephones, cell phones, tablets, phablets, personal digital assistants (PDAs), laptop computers, digital cameras, camcorders, viewfinders, micro-displays, 3-D displays, vehicles, a large area wall, theater or stadium screen, or a sign. Various control mechanisms may be used to control devices fabricated in accordance with the present invention, including passive matrix and active matrix. Many of the devices are intended for use in a temperature range comfortable to humans, such as 18 C to 30 C, and more preferably at room temperature (20-25 C), but could be used outside this temperature range, for example, from −40 C to +80 C.

To increase the efficiency of OLED devices, it is often desirable to use wavelength- and viewing angle-independent means to efficiently outcouple light out of the device. Conventional OLEDs fabricated on glass substrates can emit only about 20% light into viewable “air modes” due to internal reflection from the glass modes into the air. Many techniques and structures may be used to outcouple glass modes, such as using scattering layers, roughening the substrate surface, using large hemispherical lenses, and the like. In some cases, an efficient technique to outcouple light is the use of microlens arrays placed on the outer surface of the device. This method often relies on stamped hemispherical microlenses, typically 5-10 μm in diameter, and often made from polymers that are attached to the rear surface of the OLEDs. The use of microlenses is wavelength and viewing angle independent, and generally can couple 1.7-2.0 times more light into air modes than a flat glass substrate.

An addition, often more difficult challenge is to couple out the waveguide modes from the OLED active region into the glass substrate or air. Conventional techniques to do so include scattering layers, including roughening the interface between a transparent anode and the underlying glass, the use of high index spheres deposited on the glass prior to covering them with an electrode material, and the use of a low index grid (LIG) arranged within the OLED, between the electrode and the other OLED layers. When coupled with microlenses to extract light from the glass modes, this technique may result in a total outcoupling enhancement of over two times the outcoupling, commonly observed in OLEDs on a flat glass substrate.

For example, a white light emitting OLED (WOLED) based on electrophosphorescence with a luminance efficiency of 50 lm/W on glass would be expected to have an efficiency of 115 lm/W using a device structure including a LIG and a microlens sheet. While the LIG employs relatively easy to achieve pattern resolutions (typically 1-5 μm), and hence is also wavelength and angle independent while being inexpensive to fabricate, the fact that the grid must be fabricated within the OLED active region may result in undesirable effects. For example, the grid typically creates non-emissive regions within each OLED, and can give rise to sports and other nonuniformities in the OLED structure and emission due to the irregularity of the effective substrate surface on which the ° LED must be deposited. Such defects may occur because typically the LIG is about 100 nm high above the substrate, which is approximately the same thickness as the OLED itself. Finally, since some of the device area that lies over the grid is nonemissive, a device including a LIG requires a higher current density to achieve the same brightness as a conventional device, although this drawback may marginally impact the ultimate light output enhancement due to the higher outcoupling of the LIG.

Disclosed herein are systems and devices that allow for outcoupling of waveguide modes that are as effective as the LIG in extracting these modes, without the disadvantages previously described. As described herein, a “buried grid” (BG) may be used, in which a grid formed from two materials with different indices of refraction is disposed outside an OLED device, such as below a lower electrode. A buried grid as described herein may be formed, for example, using a combination of imprint lithography followed by simple lamination of a polymer sheet onto its surface. The structure may be completely buried, i.e., below the electrode, providing a base onto which electrode material such as ITO and subsequent OLED active layers may then be deposited, thus avoiding non-emissive regions and surface features that occur in a conventional LIG design.

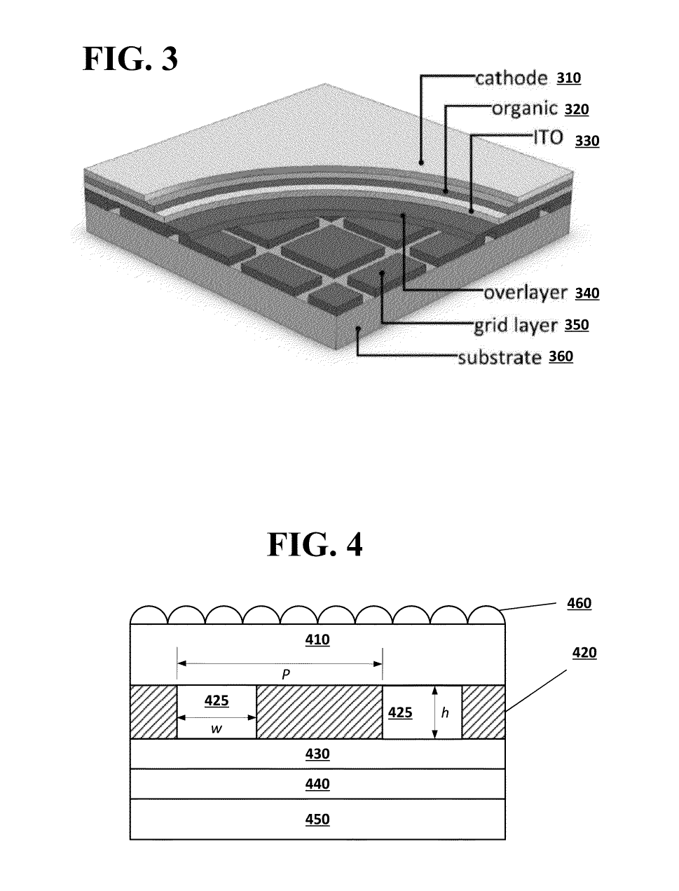

FIG. 3 shows an example structure of a device including a BG outcoupling layer as disclosed herein. The device may include a substrate 360, adjacent to which is deposited a mixed-index layer 350 that includes one or more materials arranged in a periodic pattern such as a grid. The example shown in FIG. 3 includes a square grid but, more generally, it will be understood that any repeating pattern may be used, including any other rectangular grid, a hexagonal grid, a triangular grid, any lattice structure, or any other space-filling pattern. The grid layer may include a single material, such that the grid lines are formed as voids within the layer 350, or it may include two materials having different refractive indices, such that the grid lines are formed of one material and the grid spacing, i.e., the rectangular, hexagonal, or other positive-area shapes within the grid, are formed of another material.

In some embodiments, an additional overlayer 340 may be disposed above die grid layer 350, as described in further detail herein. For example, a thin, high-index layer, such as a polymer sheet, may be applied or laminated onto the surface of the grid, leaving voids over each narrow grid line.

An electrode layer 330, such as a layer of ITO, may be disposed over the substrate surface and the grid. Additional OLED layers may then be disposed above the electrode 330, such as one or more organic layers 320, an electrode 310 such as a cathode, and other layers as are used in conventional devices. When combined with microlenses disposed below the substrate 360, a buried grid device as shown in FIG. 3 and described herein may provide an improvement of the outcoupling efficiency of up to 2.5 times.

FIG. 4 shows a schematic representation of a portion of a device having a buried grid as described herein. FIG. 4 is shown with the substrate 410 positioned closer to the top of the page, such that layers described herein as disposed “over” the substrate are illustrated as being closer to the bottom of the page than the substrate. As indicated earlier, for consistency, “top” as used herein refers to a position furthest away from the substrate, while “bottom” refers to a position closest to the substrate. The device may include a substrate 410, which may be glass, plastic, metal foil, a polymer, or any other substrate suitable for use with a conventional OLED. A mixed-index layer as previously described may be disposed above the substrate 410, and between the substrate 410 and the bottom electrode 430 of the device. The mixed-index layer may include two materials 420, 425 arranged in a pattern such as a grid, parallel to the electrode 430. One material 425 may be disposed in grid lines and the other material 420 within the grid spacing.

The geometry of the grid may be defined by the grid line width w, the grid height h, and the grid periodicity P as shown. In some embodiments, the grid may have a periodicity dictated by or selected based upon the wavelength of light emitted by the device. For example, as described in further detail herein, it may be preferred for the grid to have a periodicity larger than the wavelength of light emitted by the device. Thus, for a device that emits in the visual wavelength, a grid periodicity of at least 1 μm, or in the range of 1-10 μm may be preferred. The grid line width may be in the range of 0.1-5 μm. The grid may have any geometry, which may be selected based upon fabrication constraints, the desired physical geometry of the device, expected outcoupling, or any other factor. In general, space-filling grid geometries may be preferred. Example geometries suitable for use with a buried grid as disclosed herein include rectangular, triangular, and hexagonal, as well as any regular lattice or any other repeated pattern. More generally, it may be preferred for the materials in the mixed-index layer to be arranged in a periodic pattern, i.e., a repeated arrangement of the materials across the mixed-index layer that is regular and consistent throughout the layer, though in some embodiments the pattern may be different in one direction than in another, parallel to the electrode, across the layer, such as where a rectangular grid is used.

The grid height h may be selected based upon the desired physical structure of the resulting device, though it may be preferred for the grid to be relatively small so as to remain in relative proximity to the bottom electrode. For example, it may be preferred for the mixed-index layer, and thus the grid, to have a grid height of not more than about 10 nm-2 μm.

In some embodiments, it may be preferred for the mixed-index layer to be relatively smooth, to have minimal or no protrusions or indentations across the surface of the layer. For example, it may be preferred for the mixed-index layer to have a planar surface closest to the electrode to a tolerance of at least 0.1-2 nm. That is, it may be preferred for the layer to have no protrusions or indentations that vary by more than 0.1-2 nm from the average surface of the layer. One way to determine the size of such protrusions or indentations is to measure the distance from the bottom of the layer, adjacent to the substrate, to the relevant point on the far surface of the layer.

The refractive indices of each material in the mixed-index layer may be selected independently. In some embodiments, it may be preferred to have a relatively large difference between the host and grid material indices. For example, it may be preferred for the difference to be at least 0.1, 0.2, 0.3, 0.4, or more. Similarly, it may be preferred for the grid material to have a relatively low index, such as 1.0, 1.0-1.5, or 1.0-3.0. Although lower indices may be preferred, in some embodiments any grid index may be used, though it may still be desirable for the grid index to be less than the index of the host material.

As previously described, additional layers such as organic layers 440 and an electrode 450 may be disposed over the bottom electrode 430, i.e., farther away from the substrate. Thus, the mixed-index grid layer may be disposed between the substrate 410 and the bottom electrode 430. In some embodiments, a microlens sheet 460 or other additional outcoupling structure may be disposed within, adjacent to, or fabricated as a part of the substrate 410 to provide further outcoupling from glass to air modes.

Various techniques may be used to fabricate the devices and structures disclosed herein. Referring to FIGS. 3 and 4, in an embodiment, voids within the mixed-index layer may provide the grid lines, thereby providing a relatively low index of refraction of n=1. However, creating voids may also introducing fabrication challenges when overcooling, such as with a polymer overlayer shown in FIG. 3. In an embodiment, the grid lines may be filled with a second material having a lower index of refraction than the host material, such as a relatively very low-index material such as Teflon® having a refractive index in the range of about 1.25-1.3, or a metal or metallic compound with a lower index of refraction, though non-metal materials may be preferred to avoid absorption losses. In both cases, conventional patterning techniques based on lithography and lift-off of photoresist patterning may be used to fabricate the grid, as will be readily understood by one of skill in the art. Alternatively or in addition, the grid may be fabricated using large scale printing on flexible, thin substrates, such as via nano-imprint lithography and related methods.

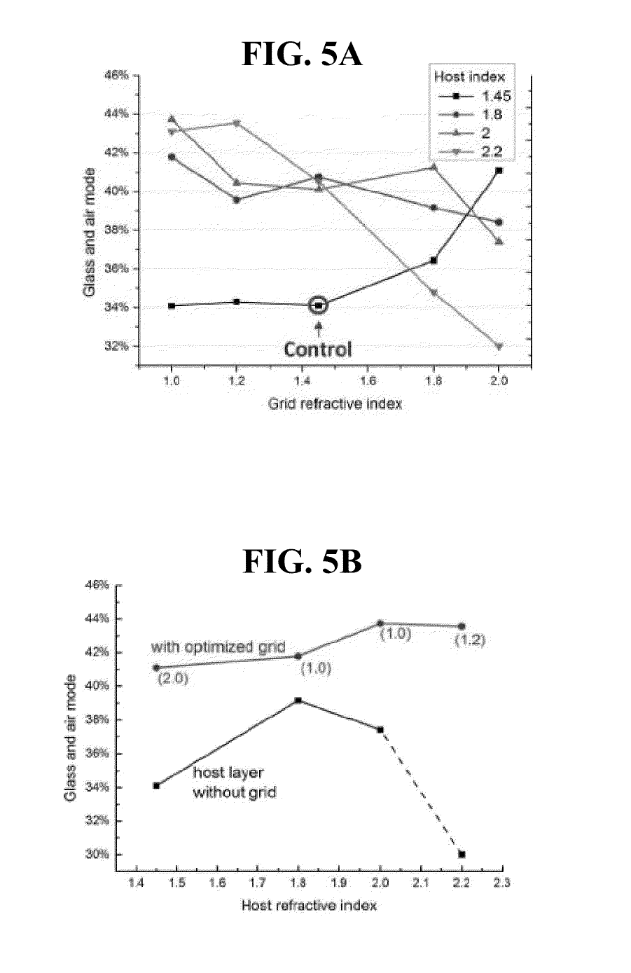

Typical pattern geometries, such as those used in the calculations in FIGS. 5-7, include a grid line width of 1 μm and a line spacing of 5 μm, although other dimensions may be used. In general, pattern resolutions of this scale are relatively simple to achieve, and the operation and effectiveness of the buried grid is not appreciably affected by occasional small defects in patterning over large substrate areas. In some embodiments, it may be preferred for the grid spacing to be relatively large compared to the wavelength of emitted light to avoid diffraction effects that will introduce chromatic and angle distortions to the emitted light. Thus, for OLEDs emitting visible light, it may be preferred for the grid spacing to be greater than about 700 nm, for example, 1-5 μm.

To fabricate a device structure as shown in FIGS. 3 and 4, a layer of the host material for the buried grid may be deposited over a substrate. Example deposition techniques include spin on deposition, such as for a sol gel mixture, or by other forms of vapor deposition for high-index metal oxides such as TiO₂. The material may then be patterned via photolithography or a similar technique and the grid lines may be etched clear to create voids. Alternatively, in an embodiment, the photoresist used to open the voids may be left on the prior layer, and a relatively low-index material such as Teflon® may be deposited across the entire surface, again by vapor deposition or any suitable technique. The photoresist then may be removed by immersion in an appropriate solvent, leaving behind only the low index grid line material in the grid lines.

In an embodiment, an interlayer may be deposited onto the surface of the mixed-index buried grid layer, as shown in FIG. 3. For example, if the grid lines are voids (with n=1), a thin polymer coating may be applied by spreading on with a doctor blade. Surface tension within the polymer layer generally prevents the polymer from entering the empty grid, line areas. If the grid lines are instead filled with a low index material, application of the polymer interlayer may be performed, for example, by spinning or doctor blade applications.

A bottom electrode may then be fabricated over the mixed-index grid layer, such as by sputtering ITO or any other suitable electrode material to form the bottom contact of the device. Additional OLED layers may be fabricated using any suitable conventional technique over the bottom electrode.

Additional outcoupling layers or structures, such as a polymer microlens array also may be fabricated on the free glass surface as previously described with respect, to FIG. 4.

One particular advantage of the use of a buried grid as disclosed herein may be that the substrate is first prepared, and then may be provided to an OLED manufacturer who can apply conventional OLED manufacturing processes without modification. That is, organic layer deposition, electrode deposition, protective layers, and other conventional OLED processing techniques may be applied to a substrate that includes a mixed-index grid layer as described herein. In addition, the buried grid may not change the appearance of the OLE) compared to devices without a buried grid. For example, the OLED may retain a “mirror” finish if there are no intervening polarizers or other optical structures between the viewer and, the device itself.

### Experimental

FIG. 5A shows simulation results of the amount of light outcoupled to glass and air modes for a device as shown in FIG. 4 as a function of the grid material refractive index, for various host refractive indices, with a square grid having a grid line width w of 0.75 μm, grid periodicity of 5 μm, and grid, height of 100 nm. The device structure used for the simulation was a 100 nm mixed-index layer, 130 nm ITO electrode, 125 nm organic layers, and a 250 nm Al electrode. FIG. 5B shows simulation results of the amount of light outcoupled to glass and air modes as a function of the host refractive index with and without an optimized grid having the refractive indices shown. As shown by FIGS. 5A and 5B, in some embodiments a higher contrast between the grid and host materials may be preferred to improve the amount of light outcoupled to glass and air modes.

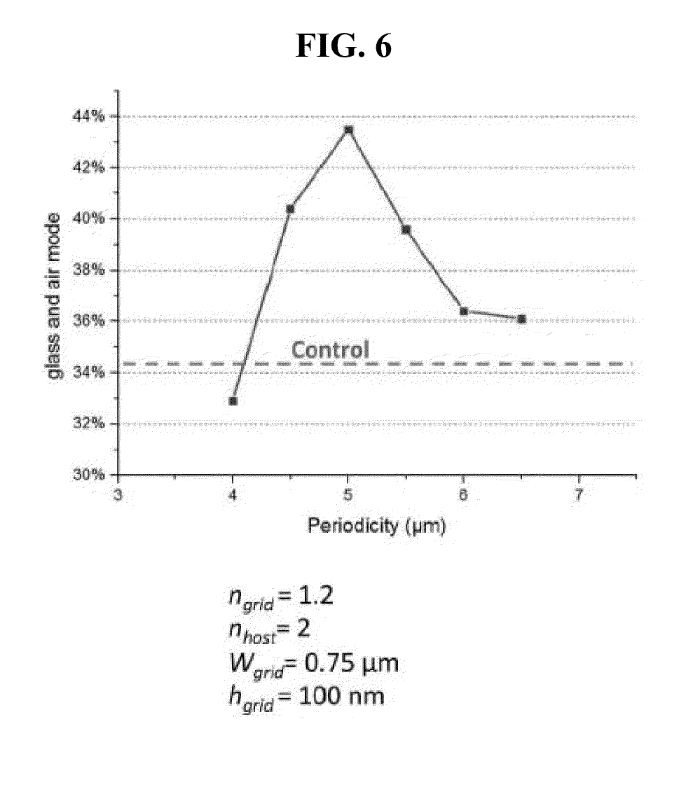

FIG. 6 shows simulation results showing the amount of light outcoupled to glass and air modes at different grid periodicities, for square grid and host materials having refractive indices of 1.2 and 2.0, respectively, a grid line width of 0.75 μm, and a grid height of 100 nm. As shown by FIG. 6, a smaller periodicity generally may be expected to provide better outcoupling, though a grid cell having too small a periodicity may block horizontal dipole emissions and thus may be less preferable than a larger grid periodicity.

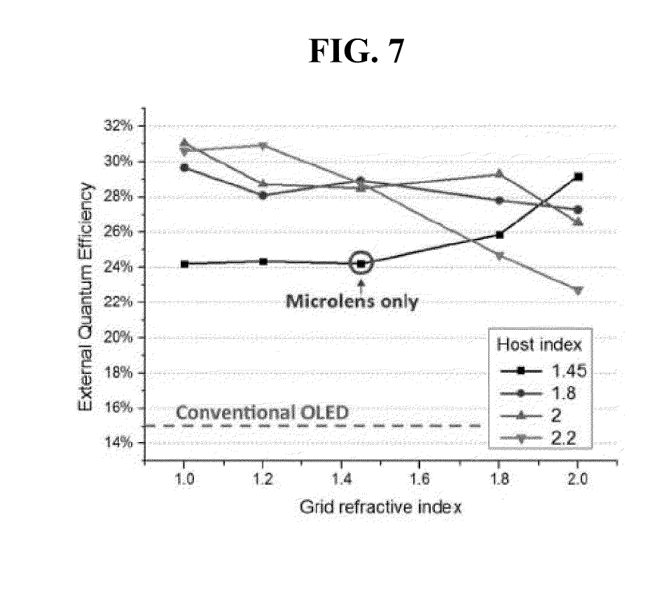

Another example calculation of the increase in outcoupling (assuming microlens arrays are place on the substrate on the surface opposite from the OLED) as a function of the indices of refraction of the grid material and “host” material (i.e., the material disposed between the grid lines in the multi-index layer) is shown in FIG. 7 for a phosphorescent OLED with a 15% external quantum efficiency (EQE). FIG. 7 shows the external quantum efficiency as a function of the grid refractive index for a variety of host refractive indices. The general structure of the device used for this simulation is the same as for FIGS. 5-6, with the addition of a microlens sheet disposed below the glass substrate. As shown, advantageous grid/host combinations occur when the grid material has a low index, preferably equal to or about equal to air at n=1.0, and the host has an index close to that of the electrode material that resides on its surface, thereby pulling the waveguide mode into the BG region. The enhancement over a conventional substrate outcoupling is 20% for a single grid period. Because this represents approximately 50% of the waveguided light, multiple grid periods may be expected to extract approximately 40% more light than that propagating in waveguide modes in a conventional flat glass substrate. When added to the factor of 1.8× expected to be extracted from glass modes using microlenses, the total increase in light output relative to a conventional OLED construction may increase by a factor of 2.5. Higher PHOLED efficacies may be possible using further-optimized structures and materials, making OLED lighting highly competitive with inorganic LEDs from several perspectives, including color rendition, efficiency, heat dissipation, luminaire form factor, and the like.

It is understood that the various embodiments described herein are by way of example only, and are not intended to limit the scope of the invention. For example, many of the materials and structures described herein may be substituted with other materials and structures without deviating from the spirit of the invention. The present invention as claimed may therefore include variations from the particular examples and preferred embodiments described herein, as will be apparent to one of skill in the art. It is understood that various theories as to why the invention works are not intended to be limiting.

1. A device comprising:
a substrate;
a mixed-index layer disposed above the substrate, the mixed-index layer comprising:
a first material having a first refractive index; and
a second material having a second refractive index different from the first refractive index, the first and second materials being disposed in a periodic pattern;
a first electrode disposed above the mixed-index layer;
an organic emissive layer disposed above the first electrode; and
a second electrode disposed above the organic emissive layer.

2. The device of claim 1, wherein the periodic pattern comprises a grid parallel to the first electrode.

3. The device of claim 2, wherein the grid has a periodicity of 1-10 μm.

4. The device of claim 2, wherein the grid has a line width of 0.1-5 μm.

5. The device of claim 2, wherein the grid has a geometry selected from the group consisting of: rectangular, hexagonal, and triangular.

6. The device of claim 1, wherein the first material has a refractive index within 0.1 of a refractive index of the first electrode.

7. The device of claim 1, wherein the difference between the first refractive index and the second refractive index is at least 0.1.

8. (canceled)

9. (canceled)

10. The device of claim 1, wherein the first material has a refractive index of 1.0 to 1.5.

11. The device of claim 1, further comprising a plurality of microlenses disposed below the substrate.

12. The device of claim 1, wherein the mixed-index layer has a thickness of 10 nm-2 μm.

13. The device of claim 1, wherein the mixed-index layer is planar to within a tolerance of 0.1-2 nm.

14. The device of claim 1, wherein the device is a device selected from the group consisting of: a flat panel display, a computer monitor, a medical monitor, a television, a billboard, a light for interior or exterior illumination and/or signaling, a heads-up display, a fully or partially transparent display, a flexible display, a laser printer, a telephone, a cell phone, a tablet, a phablet, a personal digital assistant (PDA), a laptop computer, a digital camera, a camcorder, a viewfinder, a micro-display, a 3-D display, a vehicle, a large area wall, theater or stadium screen, and a sign.

15. A method comprising:
fabricating a mixed-index layer in a pattern over a substrate, the mixed-index layer comprising a high-index material and a low-index material;
depositing a first electrode over the patterned mixed-index layer;
depositing an organic emissive layer over the first electrode; and
depositing a second electrode over the organic emissive layer.

16. The method of claim 15, wherein the step of fabricating the mixed-index layer comprises:
depositing a first high-index material in a layer over the substrate;
removing the pattern from the first high-index material to form a patterned void; and
depositing a second high-index material in a layer over the remaining first high-index material and over the patterned void.

17. The method of claim 15, wherein the step of fabricating the low-index layer comprises:
depositing a first high-index material over the substrate;
removing the pattern from the first high-index material;
depositing a low-index material over the high-index material and in the pattern; and
removing the low-index material from above the high-index material.

18. The method of claim 15, wherein the pattern comprises a grid disposed parallel to the first electrode.

19. The method of claim 18, wherein the grid has a periodicity of 1-10 μm.

20-22. (canceled)

23. The method of claim 18, wherein the difference between the first refractive index and the second refractive index is at least 0.1.

24-28. (canceled)

29. The method of claim 15, wherein the mixed-index layer is planar to within a tolerance of 0.1-2 nm.
